(19) United States
(12) Patent Application Publication
(10) Pub. No.: US 2026/0344472 A1
(43) Pub. Date: Oct. 29, 2026

(54) INTEGRATED CIRCUIT (IC) PACKAGE HAVING A SUBSTRATE WITH EMBEDDED METAL LAYERS UNDER THE SURFACES OF THE SUBSTRATE

(71) Applicant: QUALCOMM Incorporated, San Diego, CA (US)

(72) Inventors: Hong Bok We, San Diego, CA (US); Joan Rey Villarba Buot, Escondido, CA (US); Aniket Patil, San Diego, CA (US)

(21) Appl. No.: 19/187,845

(22) Filed: Apr. 23, 2025

(51) Int. Cl. H10W 70/65; H10W 70/05; H10W 70/685

(52) U.S. Cl. CPC H10W 70/65; H10W 70/05; H10W 70/095; H10W 70/685

(57) ABSTRACT

An electronic device having an integrated circuit (IC) package having a substrate with embedded metal layers under the surfaces of the substrate is disclosed. The substrate has a single core layer. The single core layer includes an embedded metal layer under its top surface and an embedded metal layer under its bottom surface, thereby increasing the density of metal layers in the substrate. Additionally, the embedded metal layers include metal interconnects which may couple to a metal via internal to the substrate or a solder ball external to the substrate. The metal interconnects are advantageously recessed below the surfaces of the substrate to improve isolation between metal interconnects. In some embodiments, when the metal interconnects are coupled to solder balls, an entire solder resist layer may be avoided, again decreasing the height of the substrate.

### TECHNICAL FIELD

The field of the disclosure relates to integrated circuit (IC) packages, and more particularly to design and manufacturing of substrates.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) may be a graphics die, processor die, memory die, system-on-a-chip (SoC) die, and the like. The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects, land grid array (LGA)) to provide an external interface between the die(s) in the IC package. The external metal interconnects can also be coupled (e.g., soldered) to traces in a printed circuit board (PCB) to attach the package to the PCB and interface its die(s) with the circuitry of the PCB. The die(s) may be mounted to the top layer of the package substrate through die interconnects. Other die(s) may also be mounted, utilizing die interconnects, to the bottom, outer metallization layer that includes metal interconnects between BGA interconnects.

### SUMMARY

Aspects disclosed in the detailed description include an integrated circuit (IC) package having a substrate with embedded metal layers under the surfaces of the substrate. Related methods are also disclosed. As a die thickness increases over design cycles to improve thermal and performance characteristics, a corresponding IC package thickness increases as well. However, device manufacturers, such as phone, tablet, and personal computer manufacturers, require that the IC package height dimensions remain the same or even shrink over one or more of these die design cycles. As a result of these device manufacturers’ requirements, there is a desire to decrease the substrate thickness to maintain the overall height of an IC package. To meet this desire, a substrate is disclosed which has a single core layer. The single core layer includes an embedded metal layer under its top surface and an embedded metal layer under its bottom surface, thereby increasing the density of metal layers in the substrate. Additionally, the embedded metal layers include metal interconnects which may interface with a via or a solder ball. The metal interconnects are advantageously recessed below the surfaces of the substrate core to improve isolation between metal interconnects. In some embodiments, when the metal interconnects are coupled to solder balls, an entire solder resist layer may be avoided, again decreasing the height of the substrate.

In this regard in one aspect, an electronic device is disclosed. The electronic device comprises an IC package. The IC package includes a substrate extending in a first direction. The substrate includes a single core layer and a first embedded metal layer under a top surface of the single core layer, the first embedded metal layer including a plurality of first metal interconnects. The substrate also includes a second embedded metal layer under a bottom surface of the single core layer, the second embedded metal layer including a plurality of second metal interconnects. The substrate also includes a plurality of metal vias coupling the plurality of first metal interconnects to the plurality of second metal interconnects through the single core layer.

In another aspect, a method for fabricating an electronic device is disclosed. The method includes forming an IC package. Forming an IC package includes forming a substrate extending in a first direction. Forming a substrate includes forming a single core layer, and forming a first embedded metal layer under a top surface of the single core layer, the first embedded metal layer including a plurality of first metal interconnects. Forming a substrate also includes forming a second embedded metal layer under a bottom surface of the single core layer, the second embedded metal layer including a plurality of second metal interconnects. Forming a substrate also includes forming a plurality of metal vias coupling the plurality of first metal interconnects to the plurality of second metal interconnects through the single core layer.

### BRIEF DESCRIPTION OF THE DRAWINGS

FIG. 1A is a side view of a three metal layer substrate having two core layers laminated together;

FIG. 1B is a side view of a stage in manufacturing the embedded metal layers of the three metal layer substrate in FIG. 1A, with each embedded metal layer formed on a side of a carrier used through the manufacturing process;

FIG. 1C is a side view of a subsequent stage in manufacturing the two core layers of the three metal layer substrate in FIG. 1A, with each core layer on a side of the carrier;

FIG. 1D is a side view of a subsequent stage in manufacturing the two core layers of the three metal layer substrate in FIG. 1A after being laminated together;

FIG. 2A is a side view of an exemplary embodiment of a substrate having a single core layer with embedded metal layers under the surfaces of the single core layer;

FIG. 2B is the same side view illustrated in FIG. 2A to illustrate feature sizes of the substrate;

FIG. 3A is a side view of another exemplary embodiment of a substrate having a single core layer with embedded metal layers under the surfaces of the single core layer;

FIG. 3B is the same side view illustrated in FIG. 3A to illustrate feature sizes of the substrate;

FIG. 4 is a flowchart illustrating an exemplary fabrication process of fabricating an electronic device including an integrated circuit (IC) package such as the three-dimensional (3D) IC (3DIC) package described in FIG. 7 below, which includes a substrate including, but not limited to, the substrates in FIGS. 2A-2B and 3A-3B having a single core layer with embedded metal layers under the surfaces of the single core layer;

FIGS. 5A-5C is a flowchart illustrating another exemplary fabrication process of fabricating an electronic device including an IC package such as the 3DIC package described in FIG. 7 below, which includes a substrate including, but not limited to, the substrates in FIGS. 2A-2B and 3A-3B having a single core layer with embedded metal layers under the surfaces of the single core layer;

FIGS. 6A-6I are exemplary fabrication stages during fabrication of the package interconnect according to the fabrication process in FIGS. 5A-5C;

FIG. 7 is a side view of a preferred embodiment of a substrate including, but not limited to, the substrates in FIGS. 2A-2B and 3A-3B having a single core layer with embedded metal layers under the surfaces of the single core layer deployed in an exemplary 3DIC;

FIG. 8 is a block diagram of an exemplary processor-based system that can include components such as an electronic device, wherein the electronic device includes a 3DIC package such as the one in FIG. 7, wherein the 3DIC package employs a substrate including, but not limited to, substrates in FIGS. 2A-2B or 3A-3B o having a single core layer with embedded metal layers under the surfaces of the single core layer and fabricated according to the fabrication processes in FIGS. 4 and 5A-5C; and

FIG. 9 is a block diagram of an exemplary wireless communications device that includes radio-frequency (RF) components formed from one or more electronic devices, wherein the electronic device includes a 3DIC package such as the one in FIG. 7, wherein the 3DIC package employs a substrate including, but not limited to, substrates in FIGS. 2A-2B or 3A-3B having a single core layer with embedded metal layers under the surfaces of the single core layer and fabricated according to the fabrication processes in FIGS. 4 and 5A-5C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an integrated circuit (IC) package having a substrate with embedded metal layers under the surfaces of the substrate. Related methods are also disclosed. As a die thickness increases over design cycles to improve thermal and performance characteristics, a corresponding IC package thickness increases as well. However, device manufacturers, such as phone, tablet, and personal computer manufacturers, require that the IC package height dimensions remain the same or even shrink over one or more of these die design cycles. As a result of these device manufacturers’ requirements, there is a desire to decrease the substrate thickness to maintain the overall height of an IC package. To meet this desire, a substrate is disclosed which has a single core layer. The single core layer includes an embedded metal layer under its top surface and an embedded metal layer under its bottom surface, thereby increasing the density of metal layers in the substrate. Additionally, the embedded metal layers include metal interconnects which may interface with a via or a solder ball. The metal interconnects are advantageously recessed below the surfaces of the substrate core to improve isolation between metal interconnects. In some embodiments, when the metal interconnects are coupled to solder balls, an entire solder resist layer may be avoided, again decreasing the height of the substrate.

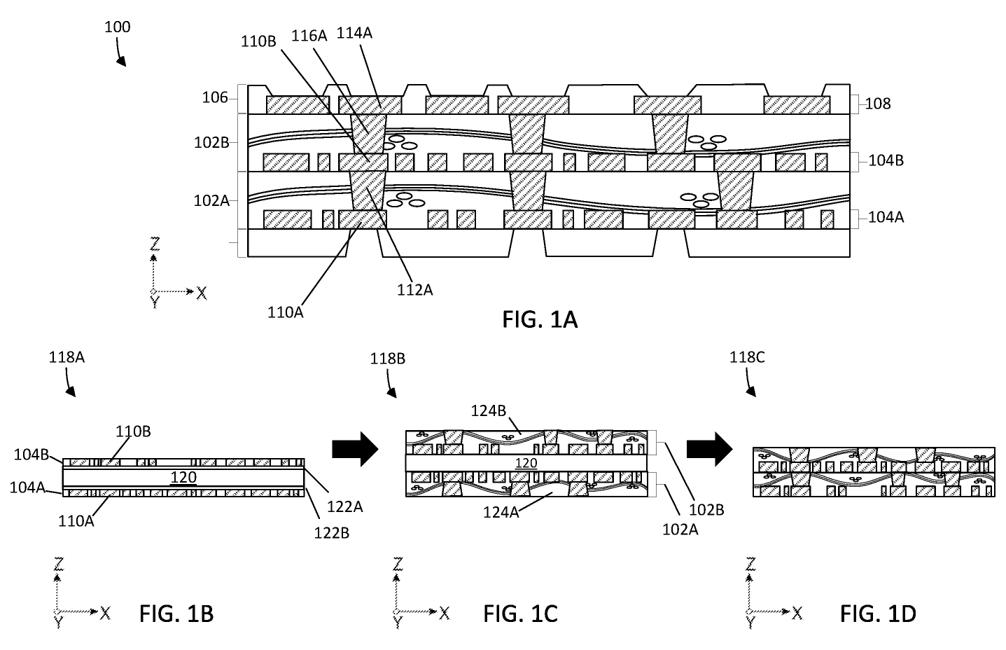

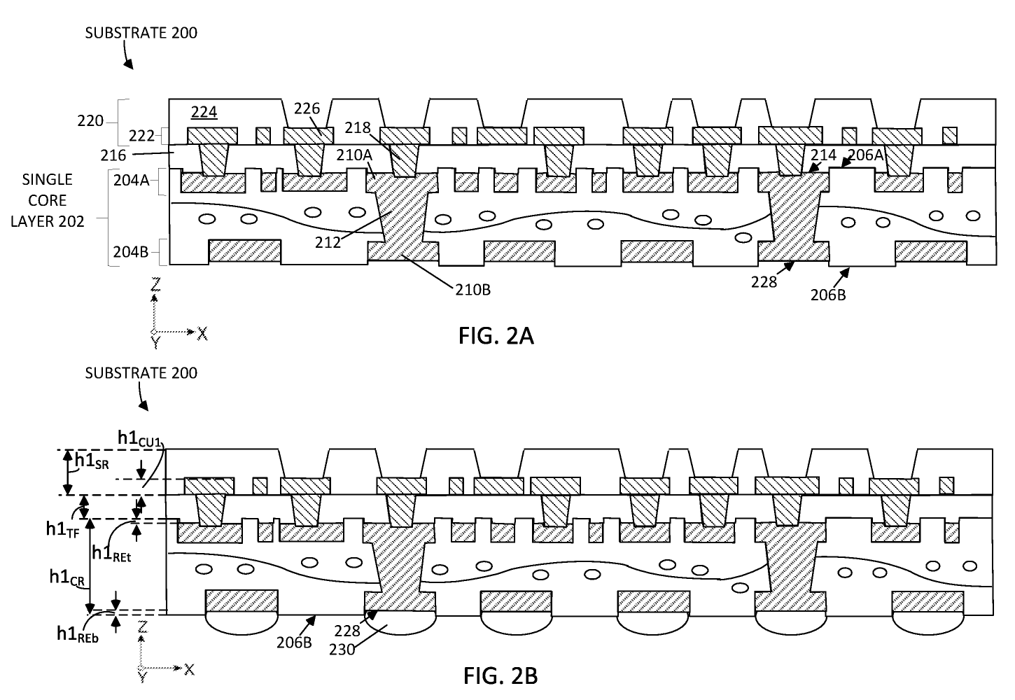

Before discussing exemplary aspects starting at FIG. 2A, a conventional three metal layer substrate 100 having two core layers laminated together is first discussed in FIGS. 1A-1D. The three metal layer substrate 100 is also referred to as a three layer embedded trace substrate (3-ETS) 100 or substrate 100. The 3-ETS includes a first core layer 102A and a second core layer 102B laminated to the first core layer 102A. Both core layers 102A-102B are comprised of glass fiber material. The first core layer 102A includes a first embedded metal layer 104A whereas the second core layer 102B includes a second embedded metal layer 104B. The substrate 100 includes a solder resist layer 106 directly adjacent to the second core layer 102B. The solder resist layer 106 includes a metal layer 108. The first embedded metal layer 104A includes metal interconnects 110A and the second embedded metal layer 104B includes metal interconnects 110B. The metal interconnects 110A are coupled to metal interconnect 110B through metal vias 112A. The metal layer 108 includes metal interconnects 114A which connect to metal interconnects 110B through metal vias 116A. Metal interconnects 114A may couple to a die. The 3-ETS 100 provides electrical connection to dies through metal interconnects 114A and to another die or a printed circuit board through metal interconnects 110A. The 3-ETS 100 also provides signal routing between metal interconnects 114A and metal interconnects 110A. As shown in FIG. 1A, to achieve three metal layers in substrate 100, separate core layers 102A-102B are needed and will be described in FIGS. 1B-1C.

FIGS. 1B-1C illustrate main stages in manufacturing the 3-ETS 100 described in FIG. 1A. FIG. 1B is a side view of a stage 118A in manufacturing of the embedded metal layers in FIG. 1A, with each embedded metal layer formed on a side of a carrier 120 used through the manufacturing process. At stage 118A, the carrier 120 has formed a thin copper (Cu) layer 122A, 122B on both the upper and lower surfaces of the carrier 120, respectively. Dry film has been deposited and patterned on the thin Cu layers 122A, 122B to plate the embedded metal layers 104A and 104B and form metal interconnects 110A and 110B.

FIG. 1C is a side view of a subsequent stage 118B in manufacturing the two core layers of the substate 100 in FIG. 1A, with each core layer on a side of the carrier 120. At stage 118B, pre-preg material 124A, 124B have been laminated to the embedded metal layer 104A and 104B, respectively. Additionally, at stage 118B, metal vias have been drilled to connect to embedded metal layers 104A and 104B forming core layers 102A and 102B.

FIG. 1D is a side view of a subsequent stage 118C in manufacturing the two core layers of the substate 100 in FIG. 1A after being laminated together. At stage 118C, core layers 102A and 102B have been detached from carrier 120, flipped, and laminated to each other. Solder resist layer 106 and metal layer 108 are deposited to the substrate at stage 118C to form the 3-ETS 100. Due to the limitations of using a carrier 120 in manufacturing stages 118A and 118B, two core layers 102A, 102B and a solder resist layer 106 are needed to achieve three metal layers.

Unlike the 3-ETS 100 described above, FIGS. 2A-2B are a side view of an exemplary embodiment of a substrate 200 having a single core layer 202 with embedded metal layers under the surfaces of the single core layer 202. The substrate 200 extends in a first direction (X, Y-axes direction). The substrate 200 also includes a first embedded metal layer 204A under a top surface 206A of the single core layer 202. The first embedded metal layer 204A includes a plurality of embedded metal interconnects 210A. The substrate 200 also includes a second embedded metal layer 204B under a bottom surface 206B of the single core layer 202. The second embedded metal layer 204B includes a plurality of embedded metal interconnects 210B. The substrate 200 also includes a plurality of metal vias 212 connecting the plurality of embedded metal interconnects 210A to the plurality of embedded metal interconnects 210B through the single core layer 202. The single core layer 202 may be a cured pre-preg material comprising glass fiber. The shape of the plurality of metal vias 212 reflects that the metal vias 212 were drilled from top to bottom in the vertical direction (Z-axis direction).

The first embedded metal layer 204A includes an outer surface 214 which is recessed from the top surface 206A of the single core layer 202. The height between the outer surface 214 and the top surface 206A of the single core layer 202 is h1_{REt} shown in FIG. 2B. The substrate 200 also includes a thin film layer 216 which includes a plurality of metal vias 218 coupled to the plurality of embedded metal interconnects 210A. The thin film layer 216 is a dielectric and comprises glass fibers. The substrate 200 also includes a solder resist layer 220 directly adjacent in the vertical direction (Z-axis direction) to the thin film layer 216. The solder resist layer 220 includes a metal layer 222 and solder resist 224. The metal layer 222 includes a plurality of metal interconnects 226 which may connect to a die (not shown).

The second embedded metal layer 204B includes an outer surface 228 which is recessed from the bottom surface 206B of the single core layer 202. The height between the outer surface 228 and the bottom surface 206B of the single core layer 202 is h1_{REb} shown in FIG. 2B.

Metal interconnects 226 may couple to a die (not shown). The substrate 200 provides electrical connection to dies through metal interconnects 226 and to another die (not shown) or a printed circuit board (PCB) (not shown) through metal interconnects 226, 210A, 210B and metal vias 218, 212. The substrate 200 also provides signal and power routing between metal interconnects 226 and metal interconnects 210A, 210B.

FIG. 2B is the same side view illustrated in FIG. 2A to illustrate sizes of certain features in the substrate 200. Below are possible height or thickness sizes for the following illustrated features:
Thickness, h1_{SR}, of the solder resist layer 220 may be between 15-30 micrometers (µm).
Thickness, h1_{CU1}, of the metal layer 222 in the solder resist layer 220 may be between 12-25 µm.
Thickness, h1_{TF}, of the thin film layer 216 may be between 12-18 µm.
Height, h1_{REt}, between the outer surface 214 and the top surface 206A of the single core layer 202 may be between 3-5 µm.
Thickness, h1_{CR}, of the single core layer 202 may be between 25-35 µm.
Height, h1_{REb}, between the outer surface 228 and the bottom surface 206B of the single core layer 202 may be between 3-5 µm.
Thickness of metal layers 204A and 204B may be between 5-7 µm.

The outer surface 228 recessed from the bottom surface 206B provides electric isolation and, thus, solder balls 230 are formed on the outer surface 228 of the second embedded metal layer 204B, as shown in FIG. 2B.

The metal used in the metal layers and vias is typically Copper (Cu). The thin film layer 216 may be Ajinomoto® build-up film (ABF).

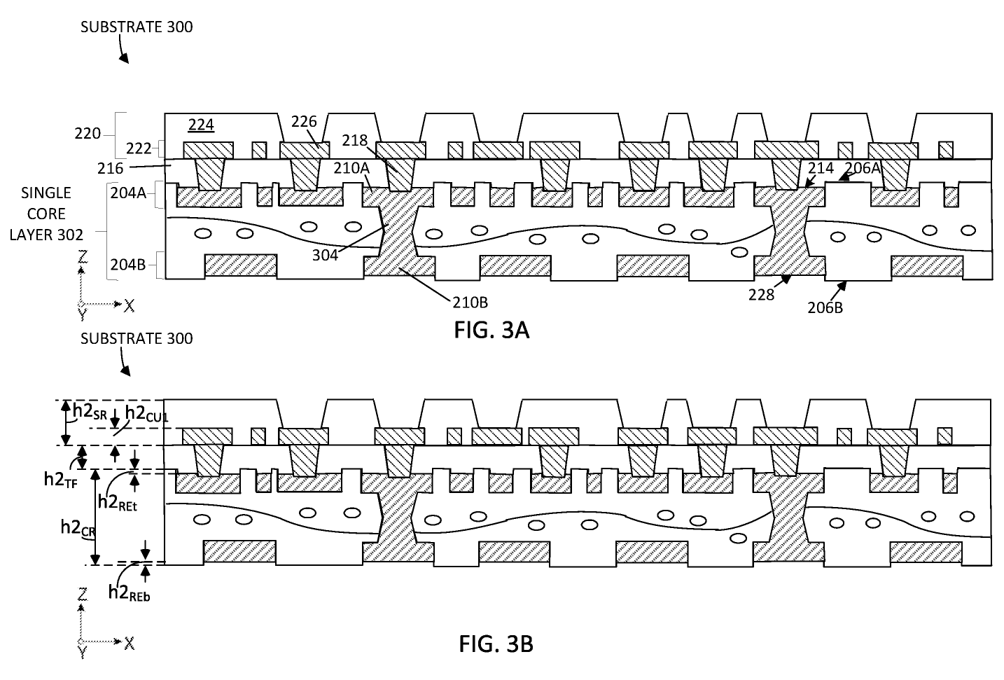

FIG. 3A is a side view of another exemplary embodiment of a substrate 300 having a single core layer 302 with embedded metal layers under the surfaces of the single core layer 302. Common elements between the substrate 300 in FIG. 3A-3B and the substrate 200 in FIGS. 2A-2B are shown with common element numbers. A plurality of metal vias 304 connect the embedded metal interconnects 210B with the embedded metal interconnects 210A. The single core layer 302 is a copper clad laminate (CCL) that includes glass fibers. The single core layer 302 is much thicker than the single core layer 202 in FIGS. 2A-2B. The shape of the plurality of metal vias 304 reflects that the metal vias 304 were drilled from the top in the vertical direction (negative Z-axis direction) to roughly half the thickness of the single core layer 302 and from the bottom in the opposite vertical direction (positive Z-axis direction) to complete a via hole.

FIG. 3B is the same side view illustrated in FIG. 3A to illustrate sizes of certain feature sizes of the substrate. Below are possible height or thickness sizes for the following illustrated features:
Thickness, h2_{SR}, of the solder resist layer 220 may be between 15-30 µm.
Thickness, h2_{CU1}, of the metal layer 222 in the solder resist layer 220 may be between 12-25 µm.
Thickness, h2_{TF}, of the thin film layer 216 may be between 15-25 µm.
Height, h2_{REt}, between the outer surface 214 and the top surface 206A of the single core layer 302 may be between 3-5 µm.
Thickness, h2_{CR}, of the single core layer 302 may be between 60-400 µm.
Height, h1_{REb}, between the outer surface 228 and the bottom surface 206B of the single core layer 302 may be between 3-5 µm.
Thickness of metal layers 204A and 204B may be between 5-7 µm.

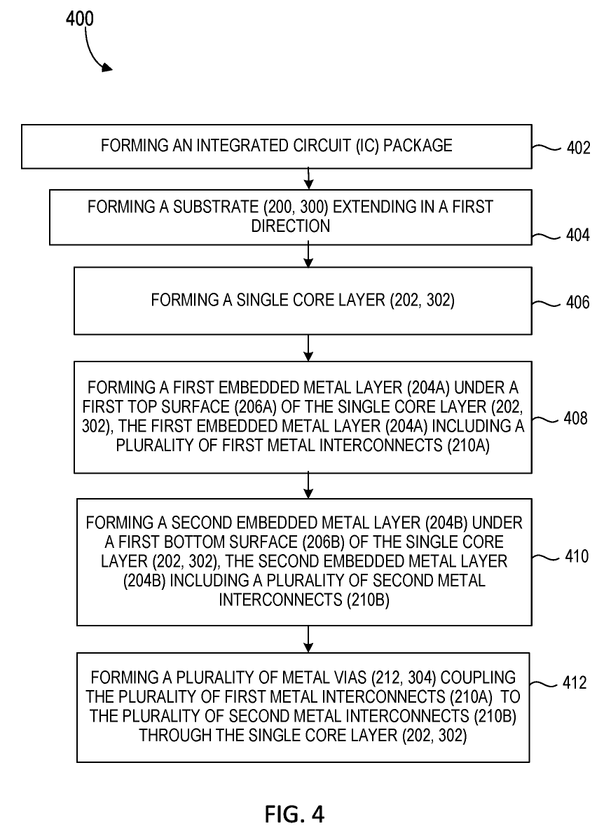

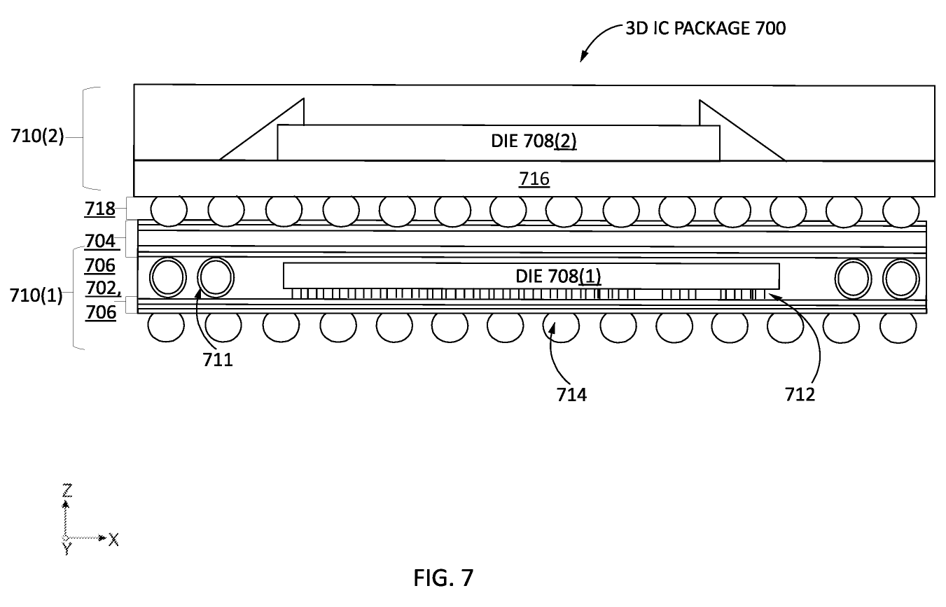

An electronic device including an IC package such as the 3DIC package (further described in FIG. 7 below) which includes a substrate including, but not limited to, the substrates in FIGS. 2A-2B and 3A-3B having a single core layer with embedded metal layers under the surfaces of the single core layer, can be fabricated by different fabrication processes. FIG. 4 is a flowchart illustrating an exemplary fabrication process of fabricating an electronic device which includes a substrate including, but not limited to, the substrates in FIGS. 2A-2B and 3A-3B having a single core layer with embedded metal layers under the surfaces of the single core layer.

In this regard, a first exemplary step in the fabrication process 400 of FIG. 4 can include forming an IC package (block 402 in FIG. 4). Forming the IC package of the fabrication process 400 can include forming a substrate 200, 300 extending in a first direction (block 404 in FIG. 4). Forming the substrate 200, 300 of the fabrication process 400 can include forming a single core layer 202, 302 (block 406 in FIG. 4). A next step in forming the substrate 200, 300 of the fabrication process 400 can include forming a first embedded metal layer 204A under a first top surface 206A of the single core layer 202, 302, the first embedded metal layer 204A including a plurality of first metal interconnects 210A (block 408 in FIG. 4). A next step in forming the substrate 200, 300 of the fabrication process 400 can include forming a second embedded metal layer 204B under a first bottom surface 206B of the single core layer 202, 302, the second embedded metal layer 204B including a plurality of second metal interconnects 210B (block 410 in FIG. 4). A next step in forming the substrate 200, 300 of the fabrication process 400 can include forming a plurality of metal vias 212, 304 coupling the plurality of first metal interconnects 210A to the plurality of second metal interconnects 210B through the single core layer 202, 302 (block 412 in FIG. 4).

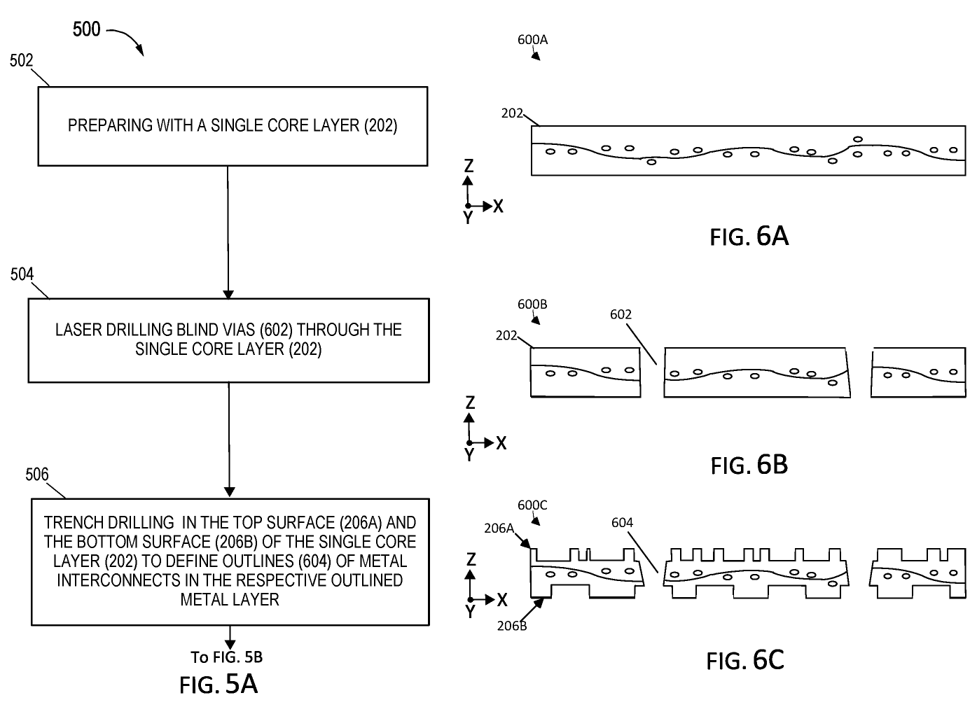

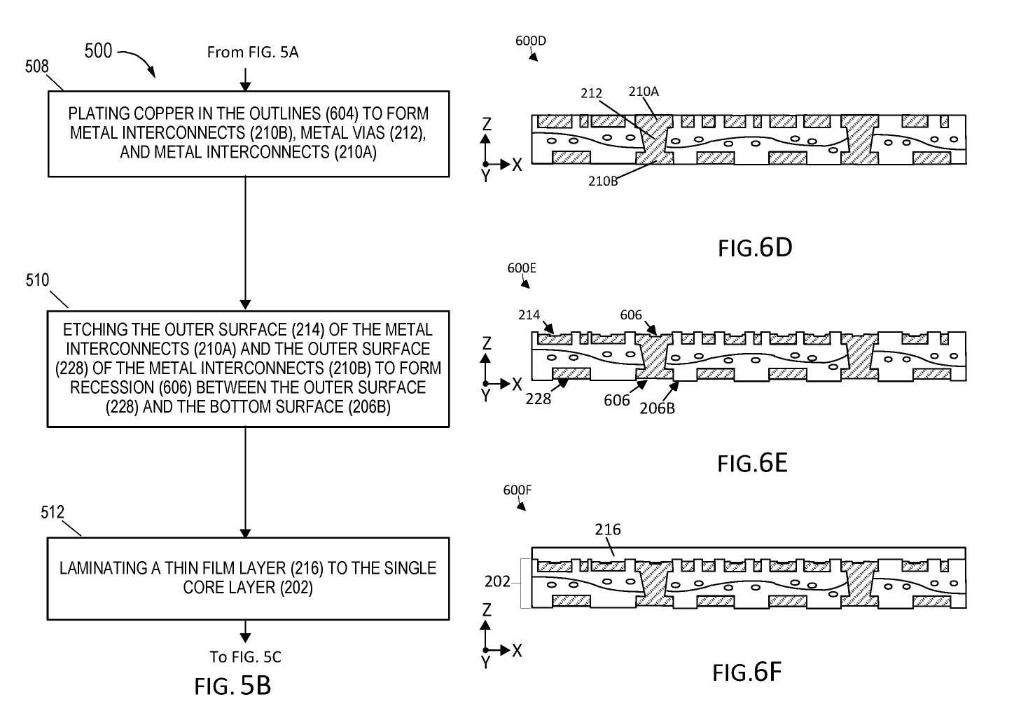

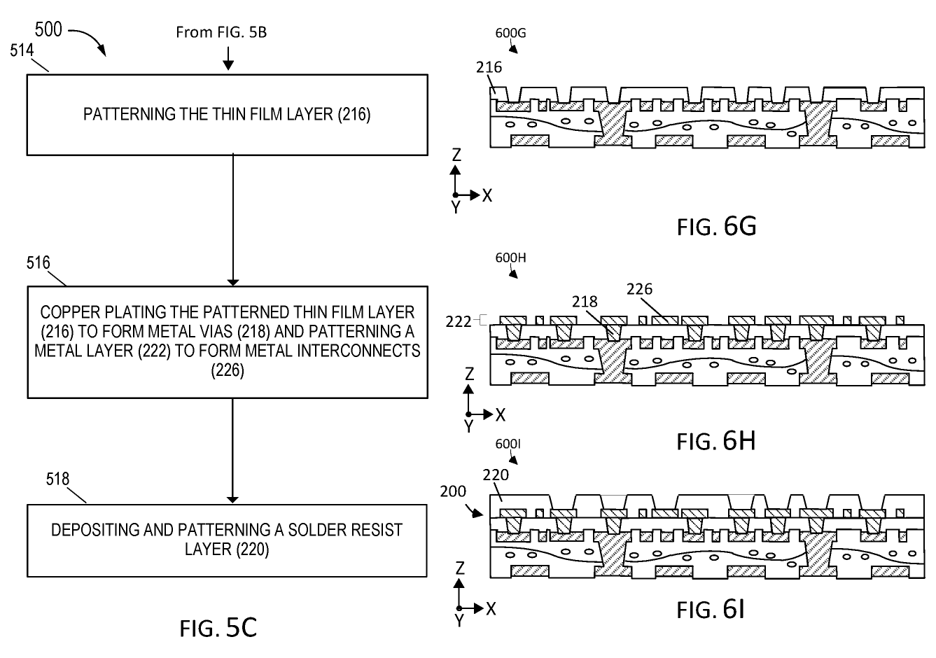

Other fabrication processes can also be employed to fabricate an electronic device including an IC package, such as the 3DIC package described in FIG. 7 below, which includes a substrate including, but not limited to, the substrate(s) in FIGS. 2A-2B and 3A-3B. In this regard, FIGS. 5A-5C is a flowchart illustrating another exemplary fabrication process of fabricating an electronic device including an IC package, such as the 3DIC package described in FIG. 7 below, which includes a substrate including, but not limited to, the substrates in FIGS. 2A-2B and 3A-3B having a single core layer with embedded metal layers under the surfaces of the single core layer. FIGS. 6A-6I are exemplary fabrication stages during fabrication of the package interconnect according to the fabrication process in FIGS. 5A-5C. Although the fabrication process in FIGS. 5A-5C is applicable to substrate in FIGS. 3A-3B, the fabrication process will be discussed in relation to the substrate in FIGS. 2A-2B.

In this regard, as shown in fabrication stage 600A in FIG. 6A, an exemplary step in the fabrication process 500 can include preparing with a single core layer 202 (block 502 in FIG. 5A). In this example, the single core layer 202 is a pre-preg core. As shown at fabrication stage 600B in FIG. 6B, a next step in the fabrication process 500 can include laser drilling blind vias 602 through the single core layer 202 (block 504 in FIG. 5A). The laser drilling of blind vias 602 can be performed by a CO₂ laser for via sizes 30 µm or larger. For smaller vias 602, an ultraviolet (UV), eximer, or pico laser may be used. As shown at fabrication stage 600C in FIG. 6C, a next step in the fabrication process 500 can include trench drilling in the top surface 206A and the bottom surface 206B of the single core layer 202 to define outlines 604 of metal interconnects in the respective outlined metal layer (block 506 in FIG. 5A). The trench drilling shown in fabrication stage 600C can be performed by either an ultraviolet (UV), eximer, or pico laser. As shown at fabrication stage 600D in FIG. 6D, a next step in the fabrication process 500 can include plating copper in the outlines 604 shown in FIG. 6C to form metal interconnects 210B, metal vias 212, and metal interconnects 210A (block 508 in FIG. 5B). As shown at fabrication stage 600E in FIG. 6E, a next step in the fabrication process 500 can include etching the outer surface 214 of the metal interconnects 210A and the outer surface 228 of the metal interconnects 210B to form recession 606 between the outer surface 228 and the bottom surface 206B (block 510 in FIG. 5B). As shown at fabrication stage 600F in FIG. 6F, a next step in the fabrication process 500 can include laminating a thin film layer 216 to the single core layer 202 (block 512 in FIG. 5B).

As shown at fabrication stage 600G in FIG. 6G, a next step in the fabrication process 500 can include patterning the thin film layer 216 (block 514 in FIG. 5C). As shown at fabrication stage 600H in FIG. 6H, a next step in the fabrication process 500 can include copper plating the patterned thin film layer 216 to form metal vias 218 and patterning a metal layer 222 to form metal interconnects 226 (block 516 in FIG. 5C). As shown at fabrication stage 600I in FIG. 6I, a next step in the fabrication process 500 can optionally include depositing and patterning a solder resist layer 220 (block 518 in FIG. 5C). Steps 514-518 may be repeated to add additional metal layers to the substrate 200.

FIG. 7 is a side view of a preferred embodiment of a substrate including, but not limited to, the substrates in FIGS. 2A-2B and 3A-3B having a single core layer with embedded metal layers under the surfaces of the single core layer deployed in an exemplary three-dimensional (3D) integrated circuit (IC) (3DIC).

FIG. 7 is a side view of an IC package 700, which in this example is a 3DIC package 700. The IC package 700 includes a package substrate 702 and an interposer substrate 704. The package substrate 702 and the interposer substrate 704 commonly route signals and power and, for convenience, may both be referred to simply as a substrate 706. Either package substrate 702, interposer substrate 704, or both may be a substrate having a single core layer, such a single core layer 202, 302 described in FIGS. 2A-2B, 3A-3B, respectively.

In this example, the 3DIC package 700 includes first and second dies 708(1), 708(2) that are included in respective first and second die packages 710(1), 710(2) that are stacked on top of each other in the vertical direction (Z-axis direction). The first die package 710(1) of the IC package 700 includes the first die 708(1) coupled to the package substrate 702. The package substrate 702 provides an electrical interface for signal routing to the first die 708(1) through solder balls 711. The first die 708(1) is coupled to die interconnects 712 (e.g., raised metal bumps, pillars) that are electrically coupled to metal interconnects (not shown) in the package substrate 702. Solder balls 714 (e.g., ball grid array (BGA) interconnects) are coupled to metal interconnects (not shown) in the package substrate 702 to provide interconnections through the package substrate 702 to the first die 708(1) through the die interconnects 712. The second die package 710(2) also includes a substrate 716. The second die package 710(2) is coupled to the interposer substrate 704 through solder balls 718. The solder balls 718 are coupled to the top surface of the interposer substrate 704 to route signals between the die 708(2) and the die 708(1).

Electronic devices that include an IC package, wherein the 3DIC package fabricated according to the fabrication process in FIGS. 5A-5C, wherein the 3DIC package employs a package interconnect including a pillar and a solder cap coupled to a bottom surface of the pillar to reduce the height of the 3DIC package, including, but not limited to, the package interconnects in FIGS. 2A-2B and 3A-3B and according to the exemplary processes in FIGS. 4 and 5A-5C, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

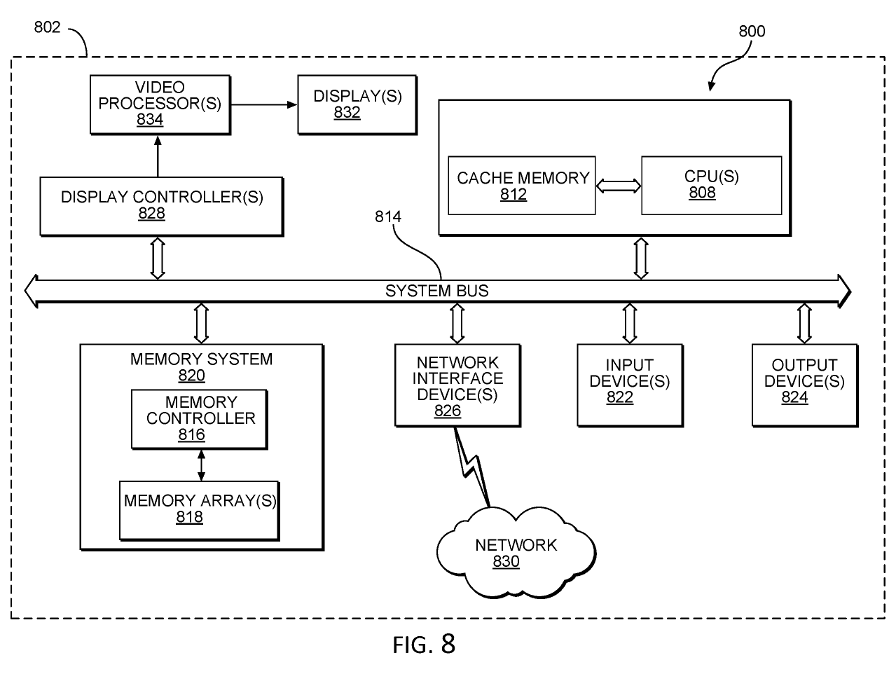

In this regard, FIG. 8 is a block diagram of an exemplary processor-based system that can include components such as an electronic device, wherein the electronic device includes a 3DIC package such as the one in FIG. 7, wherein the 3DIC package employs a substrate including, but not limited to, substrates in FIGS. 2A-2B or 3A-3B having a single core layer with embedded metal layers under the surfaces of the single core layer and fabricated according to the fabrication processes in FIGS. 4 and 5A-5C and according to any exemplary aspects disclosed herein. In this example, the processor-based system 800 may be assembled into one electronic device and a 3DIC package(s) 802 including a substrate such as substrates 200 and 300 in FIGS. 2A-2B and FIGS. 3A-3B, respectively. The processor-based system 800 includes one or more central processing unit (CPU) 808 which may also be referred to as CPU cores or processor cores. The CPU 808 may have cache memory 812 coupled to the CPU 808 for rapid access to temporarily stored data. The CPU 808 is coupled to a system bus 814 and can intercouple server and client devices included in the processor-based system 800. As is well known, the CPU 808 communicates with these other devices by exchanging address, control, and data information over the system bus 814. For example, the CPU 808 can communicate bus transaction requests to a memory controller 816, as an example of a client device. Although not illustrated in FIG. 8, multiple system buses 814 could be provided, wherein each system bus 814 constitutes a different fabric.

Other server and client devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. Each of the memory system(s) 820, the one or more input devices 822, the one or more output devices 824, the one or more network interface devices 826, and the one or more display controllers 828 can be provided in the same or different electronic devices. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display controller(s) 828 sends information to the display(s) 832 to be displayed via one or more video processor(s) 834, which process the information to be displayed into a format suitable for the display(s) 832. The display controller(s) 828 and video processor(s) 834 can be included as ICs in the same or different electronic devices, and in the same or different electronic devices containing the CPU 808, as an example. The display(s) 832 can include any type of display, including, but not limited to, a cathode ray tube (CRT), a liquid crystal display (LCD), a plasma display, a light emitting diode (LED) display, etc.

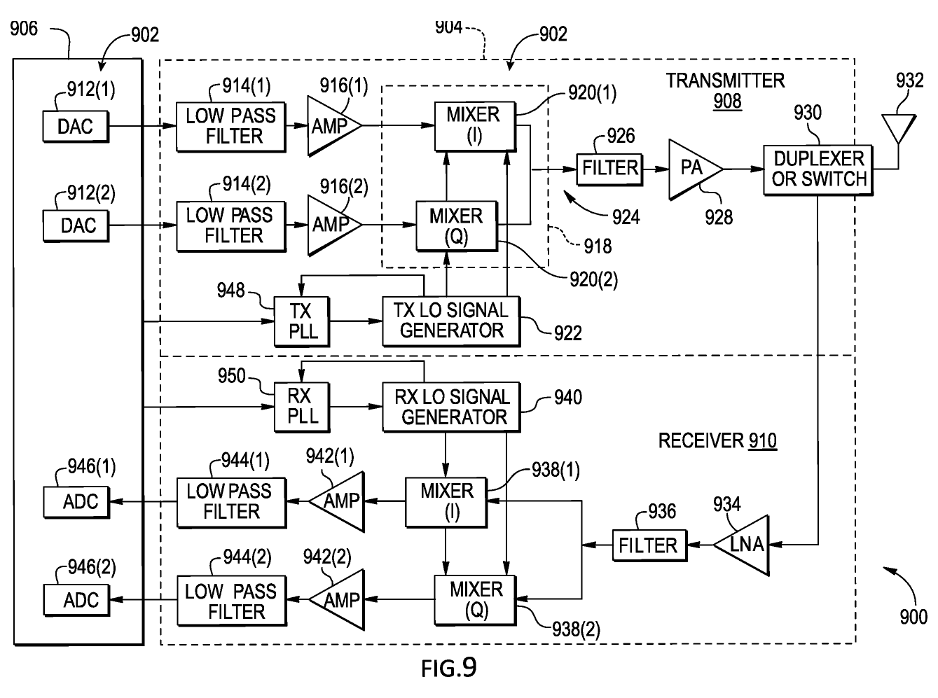

FIG. 9 is a block diagram of an exemplary wireless communications device 900 that includes radio-frequency (RF) components formed from one or more electronic devices, wherein the electronic device 900 includes a 3DIC package such as the one in FIG. 7, wherein the 3DIC package employs a substrate 902 including, but not limited to, substrates 200 or 300 in FIGS. 2A-2B or 3A-3B having a single core layer with embedded metal layers under the surfaces of the single core layer and fabricated according to the fabrication processes in FIGS. 4 and 5A-5C and according to any exemplary aspects disclosed herein. The wireless communications device 900 may include or be provided in any of the above-referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals (e.g., I and Q output currents) for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency up-conversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Down-conversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency up-conversion, while the RX LO signal generator 940 generates the I and Q RX LO signals used for frequency down-conversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An electronic device, comprising:
an integrated circuit (IC) package, comprising:
   a substrate extending in a first direction, the substrate comprising:
      a single core layer;
      a first embedded metal layer under a top surface of the single core layer, the first embedded metal layer including a plurality of first metal interconnects;
      a second embedded metal layer under a bottom surface of the single core layer, the second embedded metal layer including a plurality of second metal interconnects; and
      a plurality of metal vias coupling the plurality of first metal interconnects to the plurality of second metal interconnects through the single core layer.

2. The electronic device of clause 1, wherein the first embedded metal layer includes an outer surface which is recessed from the top surface of the single core layer.

3. The electronic device of clause 1 or clause 2, wherein the substrate further comprises:
a thin film layer comprising a plurality of second metal vias coupled to the plurality of first metal interconnects.

4. The electronic device of clause 3, wherein the substrate further comprises:
a solder resist layer directly adjacent to the thin film layer.

5. The electronic device of clause 4, wherein the solder resist layer comprises a metal layer.

6. The electronic device of any of clause 1 to clause 5, wherein the second embedded metal layer includes an outer surface which is recessed from the bottom surface of the single core layer.

7. The electronic device of clause 6, wherein the substrate further comprises:
a plurality of solder balls coupled to the plurality of second metal interconnects without a solder resist layer between the plurality of solder balls.

8. The electronic device of any of clause 1 to clause 7, wherein the single core layer comprises glass fabric.

9. The electronic device of clause 8, wherein the single core layer is a pre-preg layer.

10. The electronic device of clause 8, wherein the single core layer is a cored substrate.

11. The electronic device of any of clause 1 to clause 10 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

12. A method of fabricating an electronic device, comprising:
forming an integrated circuit (IC) package, comprising:
   forming a substrate extending in a first direction, comprising:
      forming a single core layer;
      forming a first embedded metal layer under a top surface of the single core layer, the first embedded metal layer including a plurality of first metal interconnects;
      forming a second embedded metal layer under a bottom surface of the single core layer, the second embedded metal layer including a plurality of second metal interconnects; and
      forming a plurality of metal vias coupling the plurality of first metal interconnects to the plurality of second metal interconnects through the single core layer.

13. The method of clause 12, wherein the first embedded metal layer includes an outer surface which is recessed from the top surface of the single core layer.

14. The method of clause 12 or clause 13, wherein forming the substrate further comprises:
forming a thin film layer comprising a plurality of second metal vias coupled to the plurality of first metal interconnects.

15. The method of clause 14, wherein forming the substrate further comprises:
forming a solder resist layer directly adjacent to the thin film layer.

16. The method of clause 15, wherein forming the solder resist layer further comprises:
forming a metal layer.

17. The method of any of clause 12 to clause 16, wherein the second embedded metal layer includes an outer surface which is recessed from the bottom surface of the single core layer.

18. The method of clause 17, wherein forming the substrate further comprises:
forming a plurality of solder balls coupled to the plurality of second metal interconnects without a solder resist layer between the plurality of solder balls.

19. The method of any of clause 12 to clause 18, wherein the single core layer comprises glass fabric.

20. The method of clause 19, wherein the single core layer is a pre-preg layer.

What is claimed is:

1. An electronic device, comprising:
an integrated circuit (IC) package, comprising:
a substrate extending in a first direction, the substrate comprising:
a single core layer;
a first embedded metal layer under a top surface of the single core layer, the first embedded metal layer including a plurality of first metal interconnects;
a second embedded metal layer under a bottom surface of the single core layer, the second embedded metal layer including a plurality of second metal interconnects; and
a plurality of metal vias coupling the plurality of first metal interconnects to the plurality of second metal interconnects through the single core layer.

2. The electronic device of claim 1, wherein the first embedded metal layer includes an outer surface which is recessed from the top surface of the single core layer.

3. The electronic device of claim 1, wherein the substrate further comprises:
a thin film layer comprising a plurality of second metal vias coupled to the plurality of first metal interconnects.

4. The electronic device of claim 3, wherein the substrate further comprises:
a solder resist layer directly adjacent to the thin film layer.

5. The electronic device of claim 4, wherein the solder resist layer comprises a metal layer.

6. The electronic device of claim 1, wherein the second embedded metal layer includes an outer surface which is recessed from the bottom surface of the single core layer.

7. The electronic device of claim 6, wherein the substrate further comprises:
a plurality of solder balls coupled to the plurality of second metal interconnects without a solder resist layer between the plurality of solder balls.

8. The electronic device of claim 1, wherein the single core layer comprises glass fabric.

9. The electronic device of claim 8, wherein the single core layer is a pre-preg layer.

10. The electronic device of claim 8, wherein the single core layer is a cored substrate.

11. The electronic device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

12. A method of fabricating an electronic device, comprising:
forming an integrated circuit (IC) package, comprising:
forming a substrate extending in a first direction, comprising:
forming a single core layer;
forming a first embedded metal layer under a top surface of the single core layer, the first embedded metal layer including a plurality of first metal interconnects;
forming a second embedded metal layer under a bottom surface of the single core layer, the second embedded metal layer including a plurality of second metal interconnects; and
forming a plurality of metal vias coupling the plurality of first metal interconnects to the plurality of second metal interconnects through the single core layer.

13. The method of claim 12, wherein the first embedded metal layer includes an outer surface which is recessed from the top surface of the single core layer.

14. The method of claim 12, wherein forming the substrate further comprises:
forming a thin film layer comprising a plurality of second metal vias coupled to the plurality of first metal interconnects.

15. The method of claim 14, wherein forming the substrate further comprises:
forming a solder resist layer directly adjacent to the thin film layer.

16. The method of claim 15, wherein forming the solder resist layer further comprises:
forming a metal layer.

17. The method of claim 12, wherein the second embedded metal layer includes an outer surface which is recessed from the bottom surface of the single core layer.

18. The method of claim 17, wherein forming the substrate further comprises:
forming a plurality of solder balls coupled to the plurality of second metal interconnects without a solder resist layer between the plurality of solder balls.

19. The method of claim 12, wherein the single core layer comprises glass fabric.

20. The method of claim 19, wherein the single core layer is a pre-preg layer.
